(19) United States
(12) Patent Application Publication
(10) Pub. No.: US 2023/0345747 A1
(43) Pub. Date: Oct. 26, 2023

(54) FLEXIBLE SUBSTRATE

(71) Applicant: Japan Display Inc., Tokyo (JP)

(72) Inventor: Takumi SANO, Tokyo (JP)

(21) Appl. No.: 18/300,537

(22) Filed: Apr. 14, 2023

(30) Foreign Application Priority Data
Apr. 22, 2022 (JP) 2022-070751

(51) Int. Cl. H10K 39/38

(52) U.S. Cl. CPC H10K 39/38; H10K 39/401

(57) ABSTRACT

According to one embodiment, a flexible substrate including an insulating base including a plurality of first strip portions, a plurality of second strip portions, and a plurality of island-shaped portions located at the intersections of the first strip portions and the second strip portions, a plurality of electric elements each including a lower electrode, an upper electrode, and an active layer located between the lower electrode and the upper electrode, and overlapping with the island-shaped portions, and a first stress relaxation layer located between the lower electrode and the active layer, wherein the first stress relaxation layer is formed of a conductive resin material.

### CROSS-REFERENCE TO RELATED APPLICATIONS

This application is based upon and claims the benefit of priority from Japanese Patent Application No. 2022-070751, filed Apr. 22, 2022, the entire contents of which are incorporated herein by reference.

### FIELD

Embodiments described herein relate generally to a flexible substrate.

### BACKGROUND

In recent years, the use of flexible substrates with flexibility and elasticity has been studied in various fields. For example, a utility form in which a flexible substrate with electric elements arrayed in a matrix is attached to a curved surface of a housing of an electronic device, a human body, or the like has been considered. For example, various sensors such as touch sensors and temperature sensors, and display elements can be applied as electric elements.

In a flexible substrate, measures need to be taken to prevent the lines from being damaged by stress caused by bending and stretching. As such measures, for example, providing a honeycomb-shaped aperture in a base material that supports lines and forming the lines in a meandering shape (meander shape) have been proposed.

### BRIEF DESCRIPTION OF THE DRAWINGS

FIG. 1 is a schematic plan view showing a flexible substrate according to an embodiment.

FIG. 2 is an enlarged plan view showing a part of the flexible substrate shown in FIG. 1.

FIG. 3 is an enlarged plan view showing an island-shaped portion shown in FIG. 2.

FIG. 4 is a plan view showing electric elements omitted in FIG. 3.

FIG. 5 is a cross-sectional view showing the flexible substrate taken along line A-B shown in FIG. 3.

FIG. 6 is a cross-sectional view showing the flexible substrate taken along line C-D shown in FIG. 3.

FIG. 7 is a plan view showing a first stress relaxation layer shown in FIG. 5 and FIG. 6.

FIG. 8 is a cross-sectional view showing a flexible substrate according to a second embodiment.

### DETAILED DESCRIPTION

In general, according to one embodiment, a flexible substrate comprising an insulating base including a plurality of first strip portions extending in a first direction and arranged in a second direction intersecting the first direction, a plurality of second strip portions extending in the second direction and arranged in the first direction, and a plurality of island-shaped portions located at the intersections of the first strip portions and the second strip portions, a plurality of electric elements each including a lower electrode, an upper electrode located above the lower electrode, and an active layer located between the lower electrode and the upper electrode, and overlapping with the island-shaped portions, and a first stress relaxation layer located between the lower electrode and the active layer, wherein the first stress relaxation layer is formed of a conductive resin material.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. Furthermore, in the description and figures of the present application, structural elements having the same or similar functions will be referred to by the same reference numbers and detailed explanations of them that are considered redundant may be omitted.

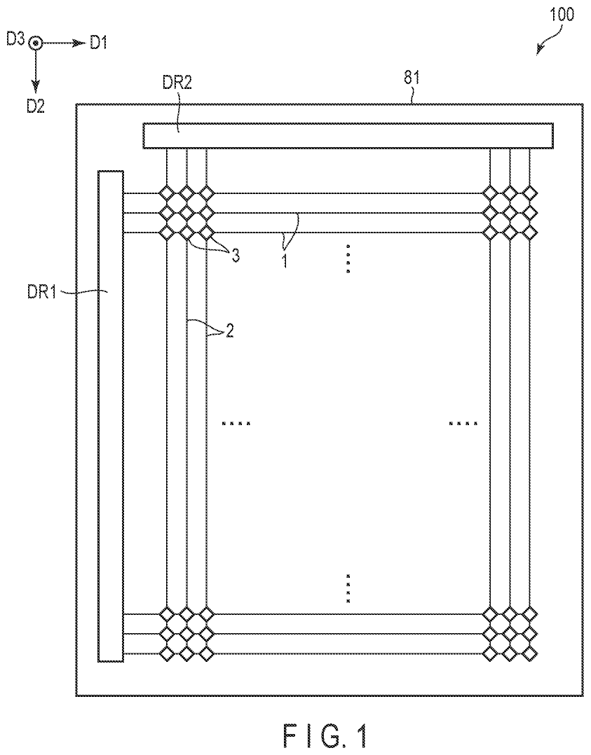

FIG. 1 is a schematic plan view showing a flexible substrate 100 according to the embodiment.

In this embodiment, a first direction D1, a second direction D2, and a third direction D3 are defined as illustrated in the figure. The first direction D1 and the second direction D2 are parallel to a main surface of the flexible substrate 100 and intersect with each other. The third direction D3 is a direction perpendicular to the first direction D1 and the second direction D2, and corresponds to a thickness direction of the flexible substrate 100. The first direction D1 and the second direction D2 intersect perpendicularly in the embodiment, but may intersect at an angle other than the perpendicular angle. In the specification, a direction toward a pointing end of an arrow indicating the third direction D3 is referred to as an upward direction and a direction toward the side opposite to the pointing end of the arrow is referred to as a downward direction. In addition, an observation position at which the flexible substrate 100 is observed is assumed to be located on the pointing end side of the arrow indicating the third direction D3, and viewing from the observation position toward the D1-D2 plane defined by the first direction D1 and the second direction D2 is referred to as planar view.

As shown in FIG. 1, the flexible substrate 100 comprises a plurality of scanning lines 1, a plurality of signal lines 2, a plurality of electric elements 3, a resin layer 81, a scanning line driver DR1, and a signal line driver DR2. The plurality of scanning lines 1, the plurality of signal lines 2, the plurality of electric elements 3, the scanning line driver DR1, and the signal line driver DR2 are provided on the resin layer 81.

Each of the plurality of scanning lines 1 extends in the first direction D1 and is arranged in the second direction D2. Each of the plurality of scanning lines 1 is connected to the scanning line driver DR1. Each of the plurality of scanning lines 2 extends in the second direction D2 and is arranged in the first direction D1. Each of the plurality of scanning lines 2 is connected to the scanning line driver DR2. Each of the plurality of electric elements 3 is located at an intersection of the scanning line 1 and the signal line 2, and is electrically connected to the scanning line 1 and the signal line 2.

The electric elements 3 are supplied with scanning signals via the scanning line 1. For example, when the electric element 3 is an element for outputting a signal such as a sensor, the output signal from the electric element 3 is supplied to the signal line 2. The scanning lines 1 and the signal lines 2 are examples of the lines which the flexible substrate 100 comprises. In addition to the scanning lines 1 and the signal lines 2, the flexible substrate 100 may comprise other types of lines such as power lines for supplying power to the electric elements 3.

The scanning line driver DR1 functions as a supply source that supplies the scanning signals to each of the scanning lines 1. In addition, the signal line driver DR2 functions as a supply source that supplies the drive signals to each of the signal lines 2, or as a signal processor that processes the output signals output to each of the signal lines 2.

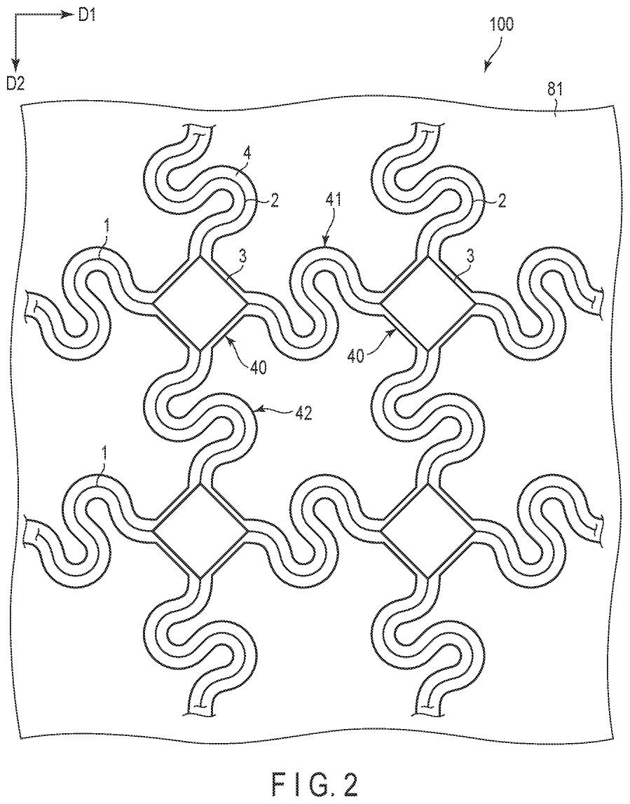

FIG. 2 is an enlarged plan view showing a part of the flexible substrate 100 shown in FIG. 1.

As shown in FIG. 2, the flexible substrate 100 comprises an insulating base 4 that supports the scanning lines 1 and the signal lines 2, in addition to the above-described elements. The insulating base 4 has elasticity and flexibility. The insulating base 4 is formed of, for example, polyimide, but is not limited to this example.

The insulating base 4 comprises a plurality of island-shaped portions 40, a plurality of first strip portions 41 and a plurality of second strip portions 42 integrally formed with the island-shaped portions 40. The insulating base 4 is formed in, for example, a mesh form. The plurality of island-shaped portions 40 are spaced apart from each other and arrayed in a matrix in the first direction D1 and the second direction D2. The plurality of island-shaped portions 40 are located at the intersections of the first strip portions 41 and the second strip portions 42. Each of the island-shaped portions 40 is formed, for example, in a square shape in planar view. The island-shaped portions 40 may be formed in other polygonal shapes or in circular or elliptical shapes. The plurality of electric elements 3 overlap with the island-shaped portions 40.

The plurality of first strip portions 41 extend generally in the first direction D1 and are arranged in the second direction D2. The first strip portion 41 connects the plurality of island-shaped portions 40 arranged in the first direction D1. The plurality of second strip portions 42 extend generally in the second direction D2 and are arranged in the first direction D1. The second strip portion 42 connects the plurality of island-shaped portions 40 arranged in the second direction D2. Each of the first strip portion 41 and the second strip portion 42 is formed in a wave shape in planar view. In other words, the first strip portion 41 and the second strip portion 42 are formed in a meander shape in planar view.

The scanning line 1 overlaps with the first strip portion 41 and extends. The signal line 2 overlaps with the second strip portion 42 and extends. In other words, both the scanning line 1 and the signal line 2 are formed in a meander shape.

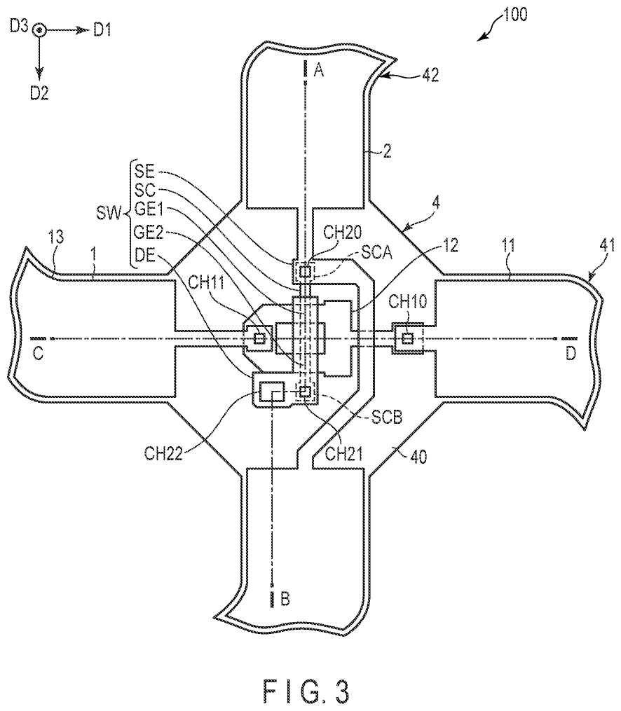

FIG. 3 is an enlarged plan view showing the island-shaped portion 40 shown in FIG. 2. In FIG. 3, illustration of the electric element 3 is omitted.

The scanning line 1 includes a first portion 11, a second portion 12 and a third portion 13. The first portion 11 and the third portion 13 overlap with the first strip portion 41. The first portion 11 and the third portion 13 are formed in the same layer as the signal line 2. The second portion 12 is located between the first portion 11 and the third portion 13. The second portion 12 is formed in a layer different from the signal line 2 and intersects the signal line 2. The first portion 11 and the second portion 12 are connected through a contact hole CH10, and the second portion 12 and the third portion 13 are connected through a contact hole CH11.

The flexible substrate 100 comprises a switching element SW. The switching element SW comprises a semiconductor layer SC, gate electrodes GE 1 and GE 2, a source electrode SE, and a drain electrode DE. The semiconductor layer SC extends in the second direction D2. An end portion SCA of the semiconductor layer SC overlaps with the signal line 2, and the other end portion SCB of the semiconductor layer SC overlaps with the drain electrode DE. In the signal line 2, an area overlapping with the semiconductor layer SC functions as the source electrode SE. The semiconductor layer SC intersects the second portion 12 of the scanning line 1 at two points in the position where the semiconductor layer SC overlaps with the drain electrode DE. In the scanning line 1, areas overlapping with the semiconductor layer SC function as the gate electrodes GE1 and GE2, respectively. In other words, the switching element SW of the illustrated example has a double-gate structure. The semiconductor layer SC is electrically connected to the signal line 2 through a contact hole CH20 at the end portion SCA, and is electrically connected to the drain electrode DE through a contact hole CH21 at the other end portion SCB. The drain electrode DE is connected to a lower electrode EL1 which will be described later, through a contact hole CH22.

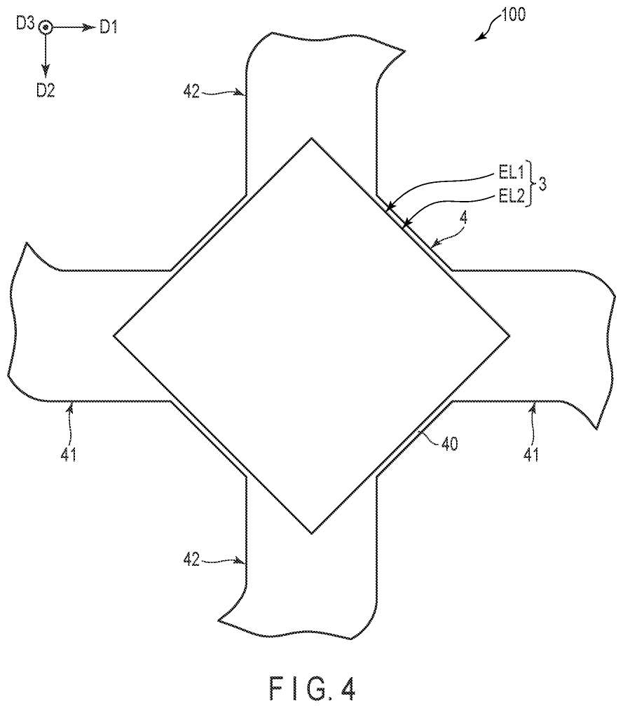

FIG. 4 is a plan view showing the electric element 3 omitted in FIG. 3.

The electric element 3 comprises a lower electrode EL1, an upper electrode EL2 located on the lower electrode EL1, and an active layer 30 which will be described later. The lower electrode EL1 and the upper electrode EL2 are formed in the same shape on the island-shaped portion 40. In the illustrated example, the lower electrode EL1 and the upper electrode EL2 are formed in a rectangular shape.

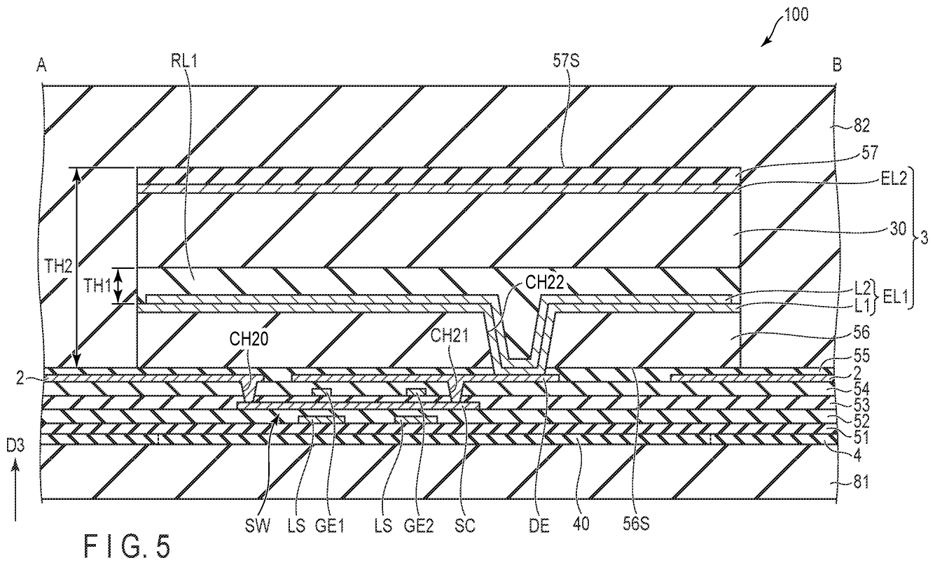

FIG. 5 is a cross-sectional view of the flexible substrate 100 taken along line A-B shown in FIG. 3.

As shown in FIG. 5, the flexible substrate 100 further comprises insulating layers 51 to 56, a sealing layer 57, a light-shielding layer LS, a first stress relaxation layer RL1, and a resin layer 82.

The insulating base 4 is located on the resin layer 81. The insulating layer 51 is located on the insulating base 4. The light-shielding layer LS is located on the insulating layer 51. The light-shielding layer LS overlaps with the gate electrodes GE1 and GE2. As a result, the light-shielding layer LS can block light traveling from the lower side to the gate electrodes GE1 and GE2. For example, the light-shielding layer LS is formed of a metal material such as aluminum (Al), titanium (Ti), silver (Ag), molybdenum (Mo), tungsten (W), copper (Cu) and chromium (Cr).

The insulating layer 52 is located on the insulating layer 51 and covers the light-shielding layer LS. The semiconductor layer SC is located on the insulating layer 52. The semiconductor layer SC is formed of, for example, polycrystalline silicon (for example, low-temperature polysilicon), but may be formed of amorphous silicon or an oxide semiconductor. The insulating layer 53 is located on the insulating layer 52 and covers the semiconductor layer SC. The gate electrodes GE1 and GE 2 are located on the insulating layer 53. The insulating layer 54 is located on the insulating layer 53 and covers the gate electrodes GE1 and GE2.

The signal line 2 and the drain electrode DE are located on the insulating layer 54. The signal line 2 is connected to the semiconductor layer SC through the contact hall CH20 formed in the insulating layers 53 and 54. The scanning line 2 can be formed of, for example, a metal material or a transparent conductive material and may have a single-layer structure or a stacked structure. The drain electrode DE is connected to the semiconductor layer SC through the contact hole CH21 formed in the insulating layers 53 and 54. The drain electrode DE is formed of, for example, the same material as that of the signal line 2. The drain electrode DE covers the gate electrodes GE1 and GE2. As a result, the drain electrode DE can block light traveling from the upper side to the gate electrodes GE1 and GE2. The insulating layer 55 is located on the insulating layer 54 and covers the signal line 2 and the drain electrode DE. The insulating layer (organic insulating layer) 56 is located on the insulating layer 55. In addition, the insulating layer 56 is located between the island-shaped portion 40 and the lower electrode EL1.

The switching element SW is located between the island-shaped portion 40 and the lower electrode EL1. The illustrated switching element SW has a double-gate structure, but may have a single-gate structure. Further, the illustrated switching element SW has a top-gate structure in which the gate electrodes GE1 and GE2 are arranged on the semiconductor layer SC, but may have a bottom-gate structure in which the gate electrodes GE1 and GE2 are arranged below the semiconductor layer SC.

The insulating layers 51 to 55 all are the inorganic insulating layers formed of an inorganic insulating material such as silicon oxide (SiO), silicon nitride (SiN), or silicon oxynitride (SiON). The insulating layer 56 is an organic insulating layer formed of an organic insulating material such as acrylic resin. The upper surface of the insulating layer 56 is substantially planarized.

The electric element 3 is located on the insulating layer 56. The electric element 3 is, for example, an organic photo diode (OPD). As described above, the electric element 3 comprises the lower electrode EL1, the active layer 30, and the upper electrode EL2.

The lower electrode EL1 is located on the insulating layer 56. The lower electrode EL1 comprises a first layer L1 and a second layer L2 which are stacked. The first layer L1 is connected to the drain electrode DE through the contact hall 22 formed in the insulating layers 55 and 56. In other words, the first layer L1 is in contact with the switching element SW. The first layer L1 and the second layer L2 are transparent electrodes formed of transparent conductive materials such as indium tin oxide (ITO) or indium zinc oxide (IZO).

The first stress relaxation layer RL1 is located between the lower electrode EL1 and the active layer 30 and is in contact with the lower electrode EL1 and the active layer 30. The first stress relaxation layer RL1 is formed of a conductive resin material, for example, silver nanoparticles, but the material is not limited to this example. The rigidity of the first stress relaxation layer RL1 is smaller than the rigidity of the insulating layer 56. In addition, the rigidity of the first stress relaxation layer RL1 is smaller than the rigidity of the insulating base 4.

The active layer 30 is located on the first stress relaxation layer RL1. The active layer 30 is formed of an electron donor (p-type semiconductor) and an electron acceptor (n-type semiconductor) which are formed of an organic material.

The upper electrode EL2 is located on the active layer 30. In other words, the active layer 30 is located between the lower electrode EL1 and the upper electrode EL2. The upper electrode EL2 is a transparent electrode formed of a transparent conductive material such as ITO or IZO. The upper electrode EL2 is connected to a feed line (not shown) and is supplied with, for example, a common potential. An electron transport layer is formed between the lower electrode EL1 and the active layer 30, and a hole transport layer is formed between the upper electrode EL2 and the active layer 30 though not illustrated in the drawing.

When receiving light, the active layer 30 generates pairs of holes and electrons. A current flows by the pairs of holes and electrons generated by the active layer 30, and an electric signal corresponding to the intensity of the current is read through the signal line 2.

The sealing layer 57 is located on the electric element 3. In other words, the sealing layer 57 covers the upper electrode EL2 of the electric element 3. The sealing layer 57 suppresses moisture from entering the active layer 30 from the upper side. The resin layer 82 covers the insulating layer 56, the electric element 3, the first stress relaxation layer RL1, and the sealing layer 57, and is in contact with the insulating layer 55.

According to the embodiment, the first stress relaxation layer RL1 is located between the lower electrode EL1 and the active layer 30. Therefore, the stress applied to the active layer 30 when the flexible substrate 100 stretches or contracts can be reduced. In addition, the layers above the first stress relaxation layer RL1 can be protected when the electric element 3 is cracked from below. In addition, since the first stress relaxation layer RL1 is formed of a conductive resin material and has conductivity, the layer can reduce the stress on the active layer 30 while ensuring conductivity between the lower electrode EL1 and the active layer 30.

In addition, according to the embodiment, the first stress relaxation layer RL1 has a thickness TH1 along the third direction D3. The thickness TH1 is 1 to 5 μm. In addition, the flexible substrate 100 has a thickness TH2 that is a thickness from a lower surface 56S of the insulating layer 56 to an upper surface 57S of the sealing layer 57. The thickness TH2 is 10 μm or less. In other words, the thickness TH2 can be adjusted to 10 μm or less by setting the thickness TH1 to 1 to 5 μm. Therefore, when the resin layer 82 is a stretchable resin film, the entry of voids caused by steps during lamination can be suppressed. Therefore, peeling of the resin layer 82 at the stretching and contraction, which is caused by voids entering the resin layer 82, can be suppressed.

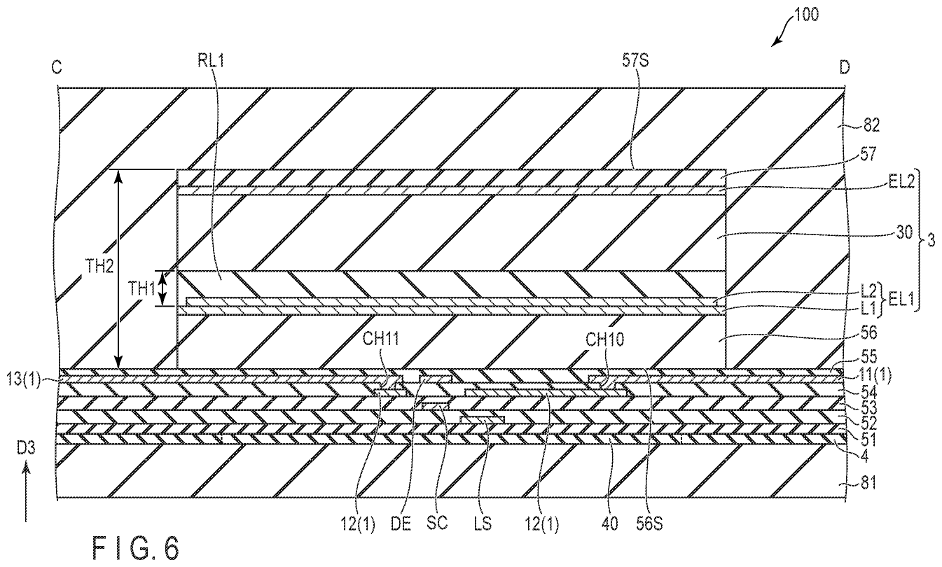

FIG. 6 is a cross-sectional view showing the first substrate 100 taken along line C-D shown in FIG. 3. The second portion 12 of the scanning line 1 is located on the insulating layer 53 and is covered with the insulating layer 54. The first portion 11 and the third portion 13 of the scanning line 1 the drain electrode DE are located on the insulating layer 54 and are covered with the insulating layer 55. The first portion 11 is connected to the second portion 12 through the contact hall CH10 formed in the insulating layer 54. The third portion 13 is connected to the second portion 12 through the contact hall CH11 formed in the insulating layer 54. The first portion 11 and the third portion 13 can be formed of, for example, a metal material or a transparent conductive material and may have a single-layer structure or a stacked structure. The second portion 12 is formed of, for example, the above metal material or an alloy formed of a combination of the above metal materials, and may have a single-layer structure or a stacked structure.

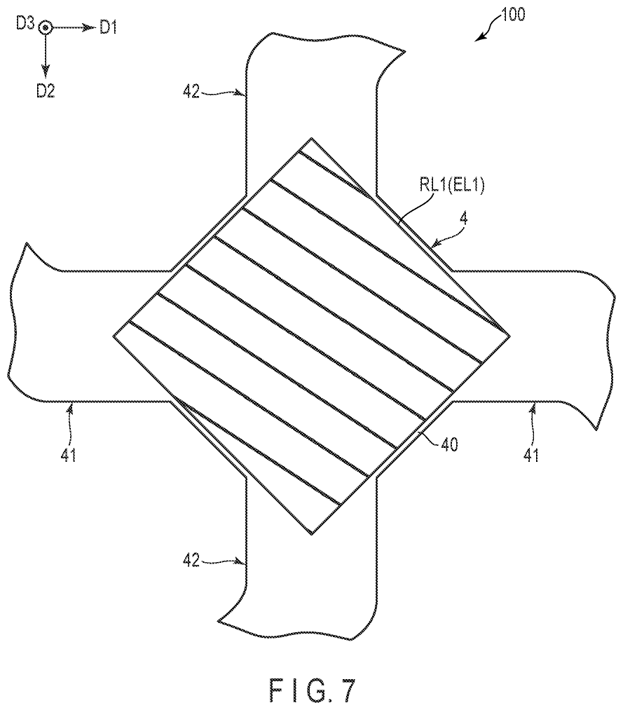

FIG. 7 is a plan view showing the first stress relaxation layer RL1 shown in FIG. 5 and FIG. 6.

The first stress relaxation layer RL1 overlaps with the entire surface of the lower electrode EL1 in planar view. In the illustrated example, the outer shape of the first stress relaxation layer RL1 is substantially the same as the outer shape of the lower electrode EL1 and is formed in a rectangular shape. The first stress relaxation layer RL1 needs only to cover the entire surface of the lower electrode EL1, and its shape is not limited to the illustrated example. In addition, the first stress relaxation layer RL1 may be formed on the entire surface of the flexible substrate 100.

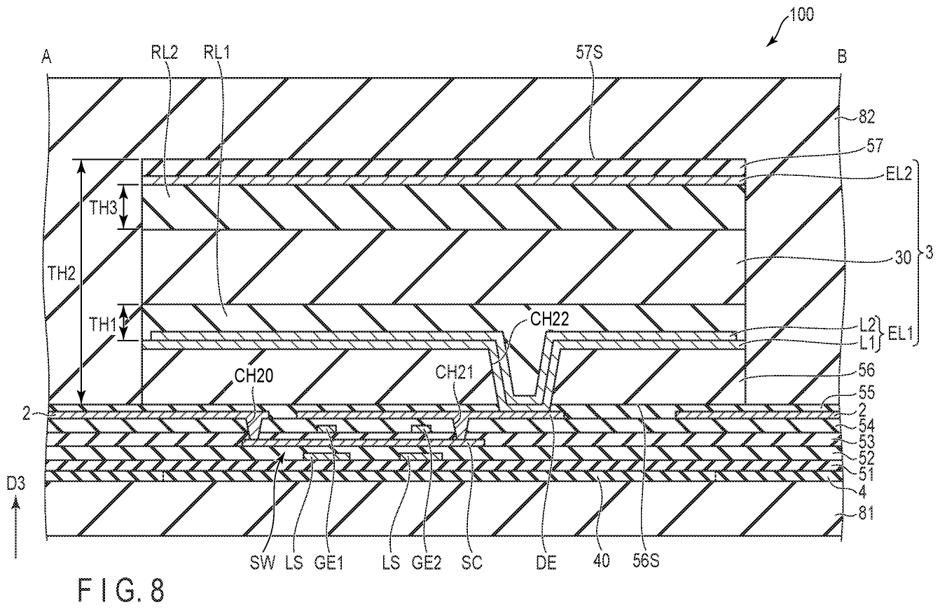

FIG. 8 is a cross-sectional view showing the flexible substrate 100 according to the second embodiment. The configuration shown in FIG. 8 is different from the configuration shown in FIG. 5 in that the flexible substrate 100 comprises a second stress relaxation layer RL2 located between the active layer 30 and the upper electrode EL2.

The second stress relaxation layer RL2 is in contact with the active layer 30 and the upper electrode EL2. The second stress relaxation layer RL2 is formed of a conductive resin material, for example, silver nanoparticles, but the material is not limited to this example. The second stress relaxation layer RL2 may be formed of the same material as that of the first stress relaxation layer RL1. The rigidity of the second stress relaxation layer RL2 is smaller than that of the insulating layer 56. The rigidity of the second stress relaxation layer RL2 is smaller than that of the insulating base 4. For example, the rigidity of the second stress relaxation layer RL2 is equal to that of the first stress relaxation layer RL1.

According to the configuration shown in FIG. 8, the stress applied to the active layer 30 when the flexible substrate 100 stretches or contracts can be reduced. In addition, the layers under the second stress relaxation layer RL2 can be protected when the electric element 3 is cracked from above. In addition, since the second stress relaxation layer RL2 is formed of a conductive resin material and has conductivity, the layer can reduce the stress on the active layer 30 while ensuring conductivity between the active layer 30 and the upper electrode EL2.

The second stress relaxation layer RL2 has a thickness TH3 along the third direction D3. The thickness TH3 is 1 to 5 μm. In addition, the thickness TH2 from the lower surface 56S of the insulating layer 56 to the upper surface 57S of the sealing layer 57 is 10 μm or less. In other words, the thickness TH2 can be adjusted to 10 μm or less by setting each of the thicknesses TH1 and TH3 to 1 to 5 μm. Therefore, when the resin layer 82 is a stretchable resin film, the entry of voids caused by steps during lamination can be suppressed. Therefore, peeling of the resin layer 82 at the stretching and contraction, which is caused by voids entering the resin layer 82, can be suppressed.

As described above, according to the embodiment, a flexible substrate capable of reducing the stress applied to the active layer during stretching and contraction can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A flexible substrate comprising:
an insulating base including a plurality of first strip portions extending in a first direction and arranged in a second direction intersecting the first direction, a plurality of second strip portions extending in the second direction and arranged in the first direction, and a plurality of island-shaped portions located at the intersections of the first strip portions and the second strip portions;
a plurality of electric elements each including a lower electrode, an upper electrode located above the lower electrode, and an active layer located between the lower electrode and the upper electrode, and overlapping with the island-shaped portions; and
a first stress relaxation layer located between the lower electrode and the active layer, wherein
the first stress relaxation layer is formed of a conductive resin material.

2. The flexible substrate of claim 1, further comprising:
an organic insulating layer located between the island-shaped portion and the lower electrode, wherein
rigidity of the first stress relaxation layer is smaller than the rigidity of the organic insulating layer.

3. The flexible substrate of claim 1, wherein
rigidity of the first stress relaxation layer is smaller than the rigidity of the insulating base.

4. The flexible substrate of claim 1, wherein
a thickness of the first stress relaxation layer is 1 to 5 μm.

5. The flexible substrate of claim 4, further comprising:
an organic insulating layer located between the island-shaped portion and the lower electrode; and
a sealing layer located on the electric element, wherein
the thickness from a lower surface of the organic insulating layer to an upper surface of the sealing layer is 10 μm or less.

6. The flexible substrate of claim 1, wherein
the first stress relaxation layer overlaps with an entire surface of the lower electrode.

7. The flexible substrate of claim 1, further comprising:
a second stress relaxation layer located between the active layer and the upper electrode, wherein
the second stress relaxation layer is formed of a conductive resin material.

8. The flexible substrate of claim 1, wherein
each of the first strip portion and the second strip portion is formed in a wave shape.
